(19) United States
(12) Patent Application Publication
(10) Pub. No.: US 2008/0308869 A1
(43) Pub. Date: Dec. 18, 2008

(54) SEMICONDUCTOR DEVICE WHICH HAS MOS STRUCTURE AND METHOD OF MANUFACTURING THE SAME

(75) Inventors: Hidekazu ODA, Tokyo (JP); Takahisa Eimori, Tokyo (JP); Jiro Yugami, Tokyo (JP); Takahiro Maruyama, Tokyo (JP); Tomohiro Yamashita, Tokyo (JP); Yukio Nishida, Tokyo (JP); Shinichi Yamanari, Tokyo (JP); Takashi Hayashi, Tokyo (JP); Kenichi Mori, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 12/194,631

(22) Filed: Aug. 20, 2008

Related U.S. Application Data
(62) Division of application No. 11/478,669, filed on Jul. 3, 2006.

(30) Foreign Application Priority Data
Jul. 11, 2005 (JP) 2005-201646

(51) Int. Cl. H01L 29/00

(52) U.S. Cl. 257/365; 257/E29.001

(57) ABSTRACT

The technology which can control a threshold value appropriately, adopting the material which fitted each gate electrode of the MOS structure from which a threshold value differs without making the manufacturing process complicated, and does not make remarkable diffusion to the channel region from the gate electrode is offered.

The PMOS transistor has a gate electrode GP, and an N type well which confronts each other via a gate insulating film with this, and the NMOS transistor has a gate electrode GN, and an P type well which confronts each other via a gate insulating film with this. While gate electrode GN includes a polycrystalline silicon layer, gate electrode GP is provided with the laminated structure of a metal layer/polycrystalline silicon layer.

### CROSS-REFERENCE TO RELATED APPLICATION

This application is a division of and claims priority under 35 U.S.C. §120 from U.S. application Ser. No. 11/478,669, filed Jul. 3, 2006, and claims the benefit of priority under 35 U.S.C. §119 from Japanese patent application No. 2005-201646 filed on Jul. 11, 2005, the entire content of which are incorporated herein by reference.

### 1. FIELD OF THE INVENTION

This invention relates to a semiconductor device which has a plurality of MOS structures. This invention is applicable to a structure of a gate electrode of a plurality of, for example MOS field-effect transistors from which a threshold value differs.

### 2. DESCRIPTION OF THE BACKGROUND ART

The term “MOS” is used for the laminated structure of metal/oxide/semiconductor in the old days, and was having the initial of Metal-Oxide-Semiconductor taken. However, especially in a field effect transistor (a “MOS transistor” is only called hereafter) which has a MOS structure, a material of the gate insulating film or the gate electrode is improved from viewpoints of integration, an improvement of a manufacturing process, etc. in recent years.

For example, in a MOS transistor, polycrystalline silicon has been adopted instead of metal as a material of a gate electrode mainly from a viewpoint of forming a source/drain in self align. Although the material of a high dielectric constant is adopted as a material of the gate insulating film from a viewpoint of improving an electrical property, the material concerned is not necessarily limited to oxide.

Therefore, as for the term “MOS”, it is not necessarily limited and adopted only as the laminated structure of metal/oxide/semiconductor, and it is not premised on such limitation also for this specification. That is, in view of common general technical knowledge, with “MOS”, it has the meaning which also includes the laminated structure of electric conductor/insulator/semiconductor widely not only as an abbreviation resulting from the origin of the word here.

[Patent Reference 1] Japanese Unexamined Patent Publication No.

[Patent Reference 2] Japanese Unexamined Patent Publication No.

[Patent Reference 3] Japanese Unexamined Patent Publication No.

### SUMMARY OF THE INVENTION

In such a background, when polycrystalline silicon is adopted as a gate electrode, in order to raise the conductivity, an impurity is implanted from the surface to polycrystalline silicon. However, when this impurity is implanted even near the gate insulating film, the impurity concerned is diffused to the channel region of the semiconductor over the gate insulating film, and the electrical property may be fluctuated. Especially this phenomenon becomes more remarkable, as a gate insulating film becomes thinner like recent years. When polycrystalline silicon forms a gate electrode of a PMOS transistor, boron may be adopted as the impurity, but the above-mentioned diffusion phenomenon becomes remarkable also in this case.

In order to avoid the above-mentioned diffusion phenomenon, keeping away the depth which implants an impurity to polycrystalline silicon from the gate insulating film is also considered. However, by this method, the depletion layer generated in the gate insulating film side of polycrystalline silicon will increase.

Or in order to avoid the above-mentioned diffusion phenomenon, and the generation of a depletion layer, adopting metal as a gate electrode is also considered. Especially by this method, when a CMOS transistor is formed, a problem occurs. The CMOS transistor is provided with both the PMOS transistor and the NMOS transistor, and must use for each gate electrode the metallic material which has a suitable work function. A manufacturing process will be made complicated although this is based on the need of adjusting the threshold value of both transistors.

This embodiment was made in view of this background, and aims at offering the technology which can control a threshold value appropriately, adopting a material suitable for each gate electrode of the MOS structure from which a threshold value differs, and does not make remarkable diffusion to a channel region from a gate electrode by devising the gate electrode structure of a MOS structure without making a manufacturing process complicated.

The technology which applies the gate electrode with which metal is formed via the silicide film which contacts on a gate insulating film, and the gate electrode with which the metal which contacts on a gate insulating film is formed to the MOS transistors of a different conductivity type is introduced to Patent Reference 1. The technology which applies the gate electrode of a pair with which the kinds of metal which contacts on a gate insulating film differ to the MOS transistor from which a conductivity type differs, respectively is introduced to Patent Reference 2. The technology which applies the gate electrode of a pair with which the impurity concentration which the metal contacting on a gate insulating film includes differs to the MOS transistor from which a conductivity type differs, respectively is introduced in Patent Reference 3.

A semiconductor device which has a MOS structure concerning this invention is provided with the first and the second semiconductor layers, the first and the second gate insulating films, and the first and the second gate electrodes. The first gate insulating film is arranged on the first semiconductor layer. The first gate electrode has a metal layer and the third semiconductor layer. The metal layer is arranged on the first gate insulating film. The third semiconductor layer is arranged on the metal layer. The second gate insulating film is arranged on the second semiconductor layer. The second gate electrode has the fourth semiconductor layer. The fourth semiconductor layer is arranged on the second gate insulating film.

A method of manufacturing a semiconductor device which has a MOS structure concerning this invention comprises the steps of: (a) forming a gate insulating film over a first semiconductor layer and a second semiconductor layer; (b) forming a metal layer over the gate insulating film; (c) leaving the metal layer in an upper part of the first semiconductor layer, and removing the metal layer from an upper part of the second semiconductor layer; (d) forming a semiconductor layer for gate electrodes over the metal layer and the second semiconductor layer; and (e) forming a first gate electrode in an upper part of the first semiconductor layer, and a second gate electrode in an upper part of the second semiconductor layer respectively, patterning the metal layer and the semiconductor layer for gate electrodes.

According to the semiconductor device concerning this invention, the first semiconductor layer, the first gate insulating film, and the first gate electrode offer the first MOS structure, and the second semiconductor layer, the second gate insulating film, and the second gate electrode offer the second MOS structure. In the first MOS structure, the threshold value can be selected by the metal layer, and the threshold value in the second MOS structure can be selected by the fourth semiconductor layer. Therefore, thickness of the metal layer can be made thin by adopting the third semiconductor layer in the first gate electrode. When patterning the third semiconductor layer and the fourth semiconductor layer, the metal layer can also be patterned collectively, and it is easy to manufacture. And the impurities do not diffuse from the first gate electrode to the first gate insulating film.

According to the manufacturing method of the semiconductor device concerning this invention, the semiconductor device concerning this invention can be manufactured. By adopting the semiconductor layer for gate electrodes in the first gate electrode especially, the thickness of the metal layer can be made thin, when patterning the semiconductor layer for gate electrodes, the metal layer can also be patterned collectively, and the manufacture is easy. And the impurities do not diffuse from the first gate electrode to the gate insulating film.

### BRIEF DESCRIPTION OF THE DRAWINGS

FIG. 1 is a cross-sectional view showing the structure of the CMOS transistor concerning Embodiment 1 of the present invention;

FIGS. 2 to 12 are cross-sectional views showing the manufacturing process of the CMOS transistor concerning Embodiment 1 of the present invention in order;

FIG. 13 is a cross-sectional view showing the structure of the CMOS transistor concerning Embodiment 2 of the present invention;

FIGS. 14 to 18 are cross-sectional views showing the manufacturing process of the CMOS transistor concerning Embodiment 2 of the present invention in order;

FIGS. 19 and 20 are cross-sectional views showing the structure of the CMOS transistor concerning Embodiment 3 of the present invention; and

FIGS. 21 and 22 are cross-sectional views showing the manufacturing method of the CMOS transistor concerning Embodiment 5 of the present invention.

### DETAILED DESCRIPTION OF THE PREFERRED EMBODIMENTS

### Embodiment 1

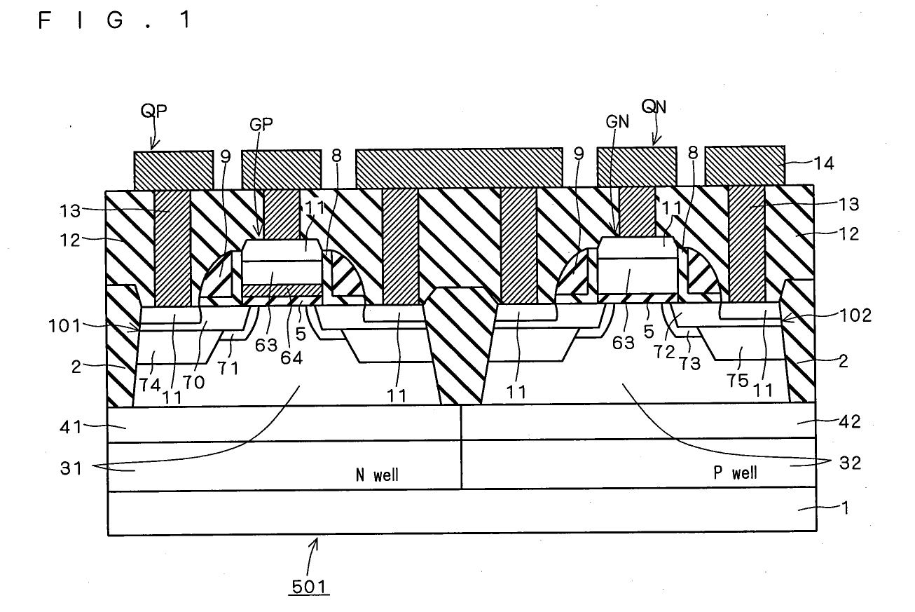

FIG. 1 is a cross-sectional view showing the structure of CMOS transistor 501 concerning this embodiment. CMOS transistor 501 is provided with PMOS transistor QP and NMOS transistor QN.

PMOS transistor QP is formed in N type well 31, and NMOS transistor QN is formed in P type well 32. Both N type well 31 and P type well 32 are formed in one main surface (in FIG. 1, it is an upside) of semiconductor substrate 1. As for N type well 31 and P type well 32, the above-mentioned main surface side is separated by element isolation insulator 2. Semiconductor substrate 1, N type well 31, and P type well 32 all adopt silicon as a main component, for example. Unless it refuses in particular, silicon is employable similarly about another impurity layers. A silicon oxide is employable as element isolation insulator 2.

N type element isolation diffusion layer 41 is formed to N type well 31, and P type element isolation diffusion layer 42 is formed to P type well 32, separating from the main surface rather than element isolation insulator 2, respectively.

PMOS transistor QP has gate electrode GP and P type source/drain layer 101 of a pair. N type well 31 which is inserted between P type source/drain layer 101 of a pair, and stands face to face against gate electrode GP functions as a channel region of PMOS transistor QP.

NMOS transistor QN has gate electrode GN and N type source/drain layer 102 of a pair. P type well 32 which is inserted between N type source/drain layer 102 of a pair, and stands face to face against gate electrode GN functions as a channel region of NMOS transistor QN.

P type source/drain layer 101 includes main layer 74 of a P type, and sublayers 70 and 71 seen from the above-mentioned main surface whose bottom is shallower than the bottom of main layer 74. Sublayer 70 is a source/drain extension of a P type, and projects in the channel region side rather than main layer 74. Sublayer 71 is a pocket of an N type, and the bottom is deeper seen from the above-mentioned main surface than the bottom of source/drain extension 70, and it projects in the channel region side rather than source/drain extension 70.

N type source/drain layer 102 includes main layer 75 of an N type, and sublayers 72 and 73 seen from the above-mentioned main surface whose bottom is shallower than the bottom of main layer 75. Sublayer 72 is a source/drain extension of an N type, and projects in the channel region side rather than main layer 75. Sublayer 73 is a pocket of a P type, and the bottom is deeper seen from the above-mentioned main surface than the bottom of source/drain extension 72, and it projects in the channel region side rather than source/drain extension 72.

Sidewall 8 of L character type in the cross section and spacer 9 with which the internal corner of sidewall 8 is filled up are formed in the perimeter of any one of gate electrodes GP and GN. As a material of sidewall 8 and spacer 9, an oxide film and a nitride film are adopted, respectively, for example.

Interlayer insulation film 12 is formed on element isolation insulator 2, source/drain extensions 70 and 72, sidewall 8, spacer 9, gate electrodes GP, and GN. As a material of interlayer insulation film 12, an oxide film is adopted, for example.

Contact plug 13 is formed, penetrating interlayer insulation film 12. Silicide layer 11 is formed in source/drain extensions 70 and 72 and gate electrodes GP and GN in the location of the lower end (above-mentioned main surface side) of contact plug 13. Source/drain extensions 70 and 72 and gate electrodes GP and GN are electrically connected with contact plug 13 via the silicide layer 11 concerned. Silicide layer 11 is made of for example, cobalt silicide. Although it is desirable to be formed from a viewpoint of making electric connection good as for silicide layer 11, it is not indispensable.

In the location of the upper end of contact plug 13, wiring layer 14 is formed on interlayer insulation film 12, and contact plug 13 and wiring layer 14 are electrically connected. As the material of contact plug 13, and the material of wiring layer 14, each can adopt metal.

Although the case where source/drain layer 101, 102 which adjoins mutually is directly linked by wiring layer 14 is exemplified in FIG. 1, the present invention is not limited to this structure. However, the present invention is preferred, when a CMOS inverter is formed, mutually connecting gate electrodes GP and GN, further. It is because adjusting a threshold value exists as a background of the present invention about a plurality of MOS structures and the adjustment concerned has big effect on operation of the CMOS inverter.

PMOS transistor QP has gate insulating film 5 between gate electrode GP, and the channel region of N type well 31. NMOS transistor QN has gate insulating film 5 between gate electrode GN, and the channel region of P type well 41. As gate insulating film 5, hafnium dioxide (HfO₂) with a high dielectric constant, and hafnium silicon oxide (HfₓSi_{y}O_{z}) and hafnium aluminium oxide (HfₓAl_{y}O_{z}) other than a silicon oxide are employable.

Sequentially from the gate insulating film 5 side, gate electrode GP includes metal layer 64, polycrystalline silicon layer 63, and silicide layer 11. Sequentially from the gate insulating film 5 side, gate electrode GN includes polycrystalline silicon layer 63 and silicide layer 11.

When adopting polycrystalline silicon as a gate electrode in a CMOS transistor, the conductivity type of these gate electrodes is usually changed. It is because it is necessary to adjust a mutual threshold value by the PMOS transistor and an NMOS transistor.

However, in this embodiment, it cannot be said that polycrystalline silicon layer 63 of gate electrode GP of PMOS transistor QP and the channel region confront each other only via gate insulating film 5. Therefore, the conductivity type of polycrystalline silicon layer 63 of gate electrode GP does not determine the threshold value of PMOS transistor QP promptly. On the other hand, since NMOS transistor QN has gate electrode GN, it is desirable to adopt an N type as the conductivity type of polycrystalline silicon layer 63 of gate electrode GN. Therefore, in the present invention, the conductivity type of polycrystalline silicon layer 63 can be made in common also in any of gate electrodes GP and GN, and an N type suitable for gate electrode GN is adopted as the conductivity type concerned in this embodiment.

Of course, since metal layer 64 of gate electrode GP and the channel region confront each other only via gate insulating film 5, it is desirable to adopt the metal which has a work function suitable for PMOS transistor QP as a material of metal layer 64. When adopting silicon as a main component of N type well 31, it is desirable to have a work function (about 5.1 eV) near the valence band of silicon as the metal concerned. As a material which has this work function, for example titanium nitride (TiN), tungsten nitride (WN), rhenium (Re), iridium (Ir), platinum (Pt), ruthenium dioxide (RuO₂), iridium dioxide (IrO₂), molybdenum nitride (MoN), and iridium dioxide (IrO₂) can be mentioned.

Thus, in this embodiment, the portion which contacts a gate insulating film in the gate electrode of the MOS transistor which has the first threshold value is made a metal layer, the portion which contacts a gate insulating film in the gate electrode of the MOS transistor which has the second threshold value is made a semiconductor layer, and the semiconductor layer of the same conductivity type as the semiconductor layer in which the MOS transistor which has the second threshold value is formed is formed on the above-mentioned metal layer. Therefore, the metal layer concerned and the semiconductor layer concerned can choose and adopt a suitable material for every threshold value of a MOS transistor. By making the side where the diffusion to the channel region of the impurity introduced into the polycrystalline silicon adopted in a gate electrode becomes remarkable between the MOS transistors which have a different threshold value the MOS transistor which has the first threshold value, the fluctuation of an electrical property by diffusion of the impurity concerned is avoidable.

When hafnium oxide is especially adopted as gate insulating film 5 and polycrystalline silicon layer 63 of gate electrode GP contacts gate insulating film 5, it is easy to generate the problem of an interface state of the so-called fermi pinning. However, since metal layer 64 contacts gate insulating film 5 in this embodiment, this problem is also avoidable. Therefore, the present invention is preferred, when adopting hafnium oxide as gate insulating film 5 and raising the dielectric constant.

And it is not necessary to change the impurity introduced into the polycrystalline silicon adopted in a gate electrode by the MOS transistor which differs in a threshold value, and the manufacturing process can be simplified in this point in the process which manufactures the MOS transistor concerning the present invention.

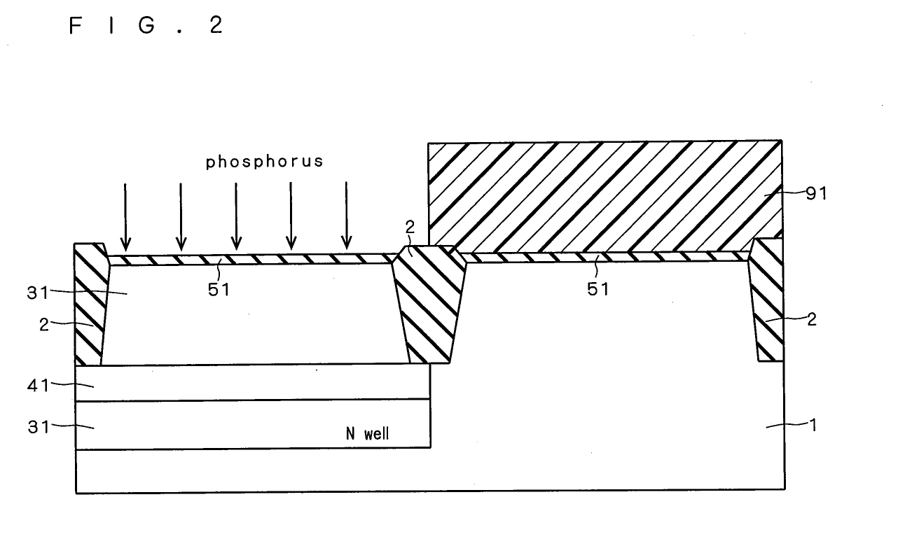

FIG. 2 through FIG. 12 are the cross-sectional views showing the manufacturing process of CMOS transistor 501 in order. First, with reference to FIG. 2, a plurality of element isolation insulators 2 are isolated and formed in one main surface of semiconductor substrate 1. The LOCOS (Local Oxidation of Silicon) method is adopted as formation of element isolation insulator 2, for example. Oxide film 51 for implantation is formed in a main surface.

Photoresist 91 is formed on the above-mentioned main surface in the region which forms NMOS transistor QN later. In FIG. 2 through FIG. 12, the case where PMOS transistor QP is formed in the left-hand side, and NMOS transistor QN is formed in right-hand side of element isolation insulator 2 shown in the center is exemplified.

Photoresist 91 is used as a mask and N type impurities are introduced into a main surface via oxide film 51 for implantation. As an N type impurity implanted, phosphorus is employable. By implantation of N type impurities, N type well 31 and N type element isolation diffusion layer 41 are formed. Photoresist 91 is removed after that.

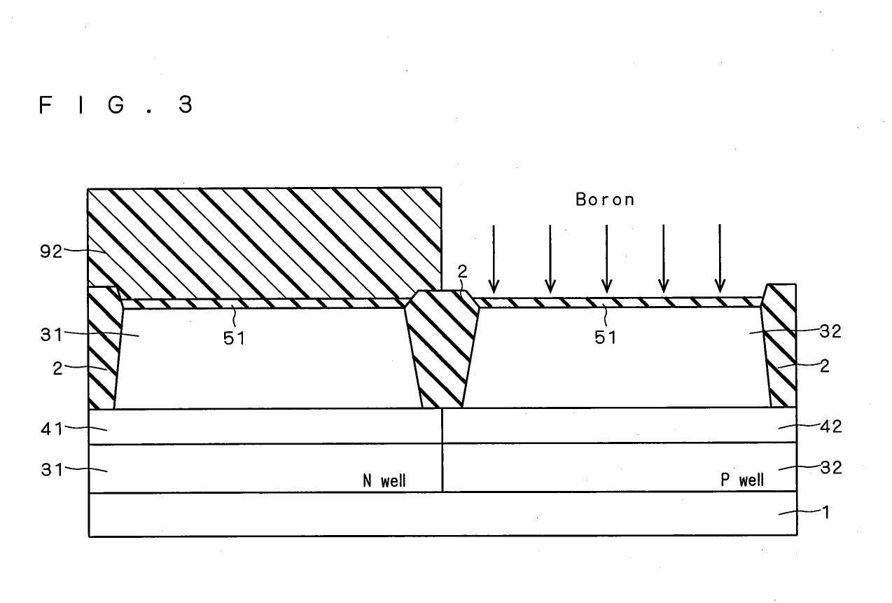

With reference to FIG. 3, photoresist 92 is formed on a main surface in the region which forms PMOS transistor QP later. Photoresist 92 is used as a mask and P type impurities are introduced into a main surface via oxide film 51 for implantation. As a P type impurity implanted, boron is employable. By implantation of a P type impurity, P type well 32 and P type element isolation diffusion layer 42 are formed.

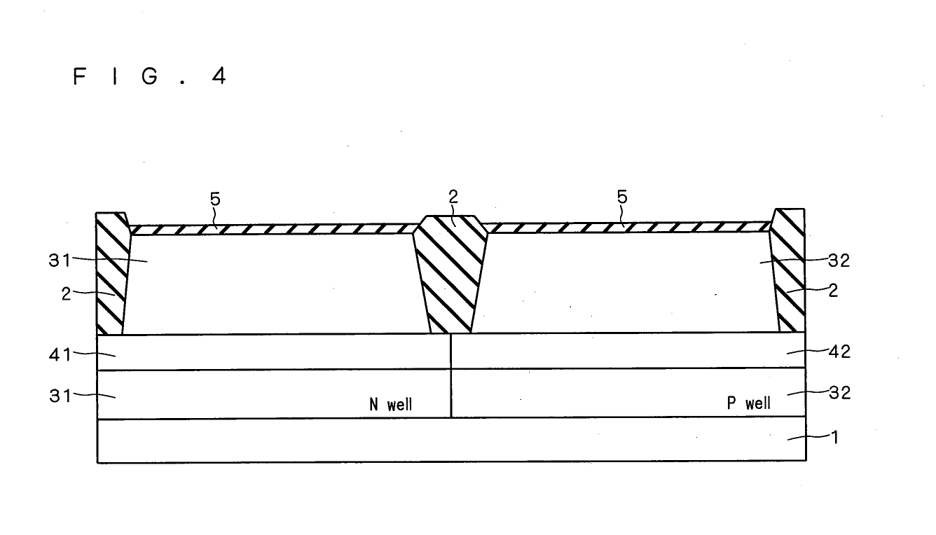

Oxide film 51 for implantation is removed with reference to FIG. 4, and gate insulating film 5 is formed on a main surface in both N type well 31 and P type well 32. Hafnium dioxide (HfO2) is employable like previous statement as gate insulating film 5.

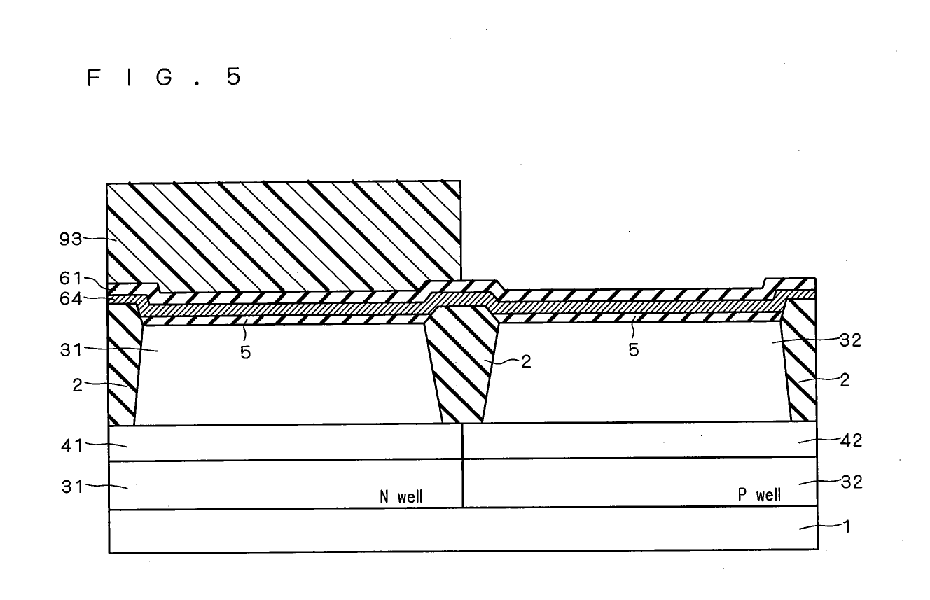

With reference to FIG. 5, over the whole surface exposed at the main surface side, metal layer 64 is formed by the thickness mentioned later on gate insulating film 5, and nitride film 61 is further formed by thickness of 10 nm on metal layer 64. The titanium nitride (TiN) generated, for example by the CVD (Chemical Vapor Deposition) method is adopted as metal layer 64. Photoresist 93 is formed on nitride film 61 in the upper part of N type well 31.

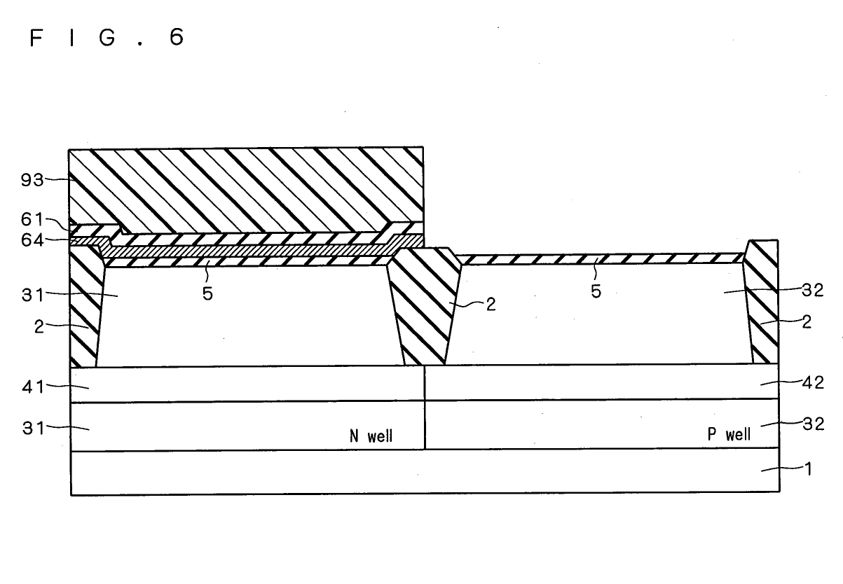

With reference to FIG. 6, nitride film 61 is patterned by using photoresist 93 as a mask. Metal layer 64 is patterned by etching metal layer 64 by using patterned nitride film 61 as a mask. Hereby, nitride film 61 and metal layer 64 are removed in the upper part of P type well 32, and are left behind in the upper part of N type well 31. Photoresist 93 and nitride film 61 are removed after that. In order to remove nitride film 61, hot phosphoric acid can be used.

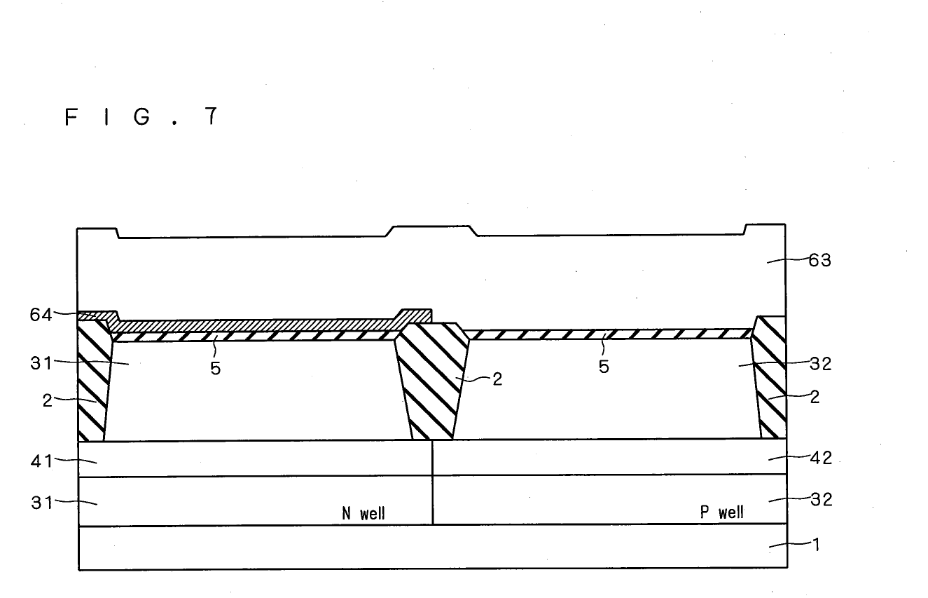

With reference to FIG. 7, over the whole surface exposed at the main surface side, polycrystalline silicon layer 63 is formed. In the upper part of N type well 31, polycrystalline silicon layer 63 will be formed on metal layer 64, and it will be formed on gate insulating film 5 in the upper part of P type well 32. In order to make the conductivity type of polycrystalline silicon layer 63 an N type, it is desirable to form polycrystalline silicon layer 63, introducing the impurity (for example, phosphorus) of an N type.

After polycrystalline silicon layer 63 is formed, also by implanting the impurity of an N type from the surface, the conductivity type of polycrystalline silicon layer 63 can be made an N type. However, the way which forms polycrystalline silicon layer 63 introducing the impurity of an N type can reduce the generation of the depletion layer at the side of gate insulating film 5 of gate electrode GN (refer to FIG. 1) rather than the case where an ion implantation is performed to near the gate insulating film 5. The thickness and impurity concentration of polycrystalline silicon layer 63 are set, for example as 100 nm and 10²⁰ cm⁻³, respectively.

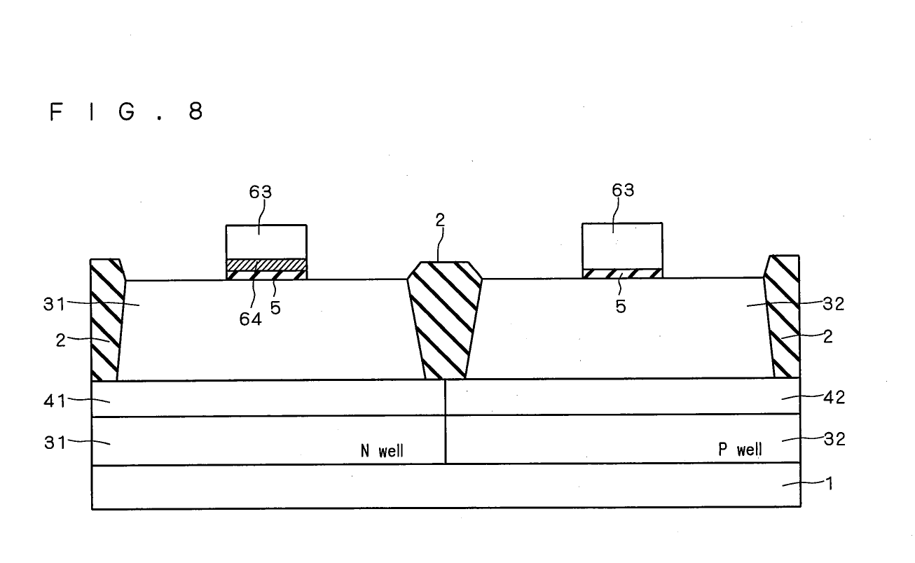

With reference to FIG. 8, a well-known photo lithography technology is adopted and polycrystalline silicon layer 63 and gate insulating film 5 are patterned. At the step which etches polycrystalline silicon layer 63, metal layer 64 can also be etched collectively. Since it is sufficient for it when metal layer 64 can offer suitable band structure with N type well 31 via gate insulating film 5, it is not necessary to thicken it and it is made to 1/10 or less thickness of polycrystalline silicon layer 63.

When etching the polycrystalline silicon layer adopted as a gate electrode, usually the amount of over-etchings is usually set to about 1/10 of the thickness of the polycrystalline silicon layer. At this embodiment, polycrystalline silicon layer 63 is formed at the same step in both the upper part of P type well 32, and the upper part of N type well 31. Therefore, the etching step can be simplified by setting the thickness of metal layer 64 below to the amount of over-etchings at the time of patterning polycrystalline silicon layer 63 in the upper part of N type well 31.

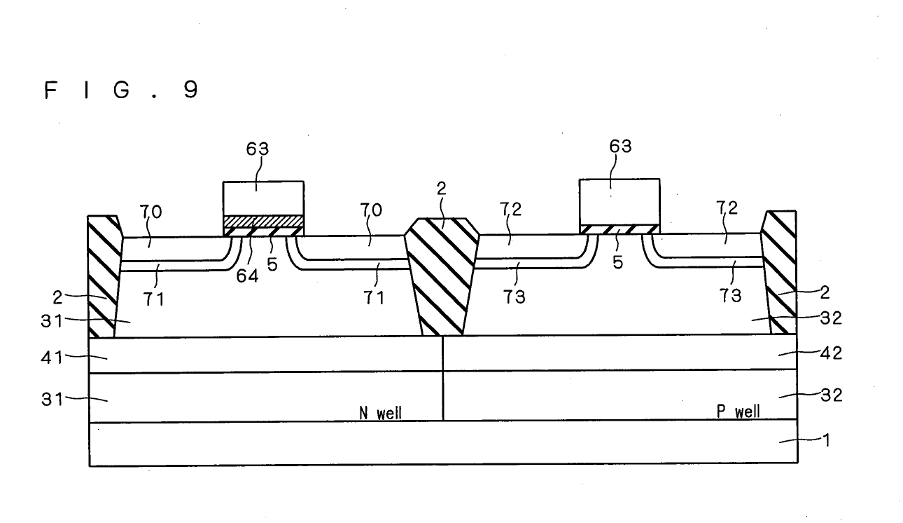

With reference to FIG. 9, in the upper part of N type well 31, source/drain extension 70 is formed by using the patterned laminated structure of polycrystalline silicon layer 63/metal layer 64/gate insulating film 5 as a mask. In the upper part of P type well 32, source/drain extension 72 is formed by using the patterned laminated structure of polycrystalline silicon layer 63/gate insulating film 5 as a mask.

Although not illustrated in detail, when forming source/drain extension 70, the upper part of P type well 32 is covered by photoresist, and P type impurities (for example, boron) are introduced to N type well 31 by ion implantation. And further, in order to inhibit a short channel effect, pocket 71 is formed, performing an ion implantation for an N type impurity (for example, arsenic) aslant to the main surface. Similarly, when forming source/drain extension 72, the upper part of N type well 31 is covered by photoresist, and N type impurities (for example, arsenic) are introduced to P type well 32 by ion implantation. And further, in order to inhibit a short channel effect, pocket 73 is formed, performing an ion implantation for a P type impurity (for example, boron) aslant to the main surface.

The dose amount and the implantation energy of these ion implantations are decided by the depth and resistance which are required to source/drain extensions 70 and 72 or pockets 71 and 73.

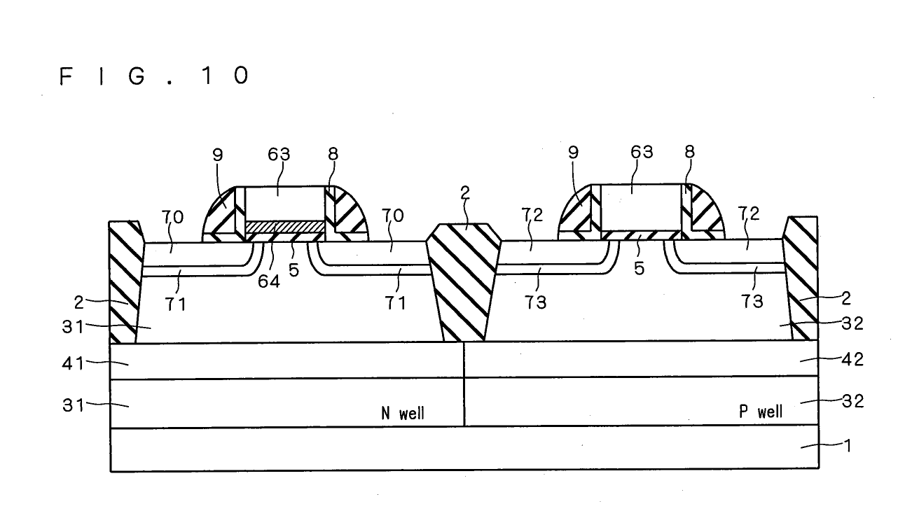

Covering all over the surface exposed at the main surface side, an oxide film and a nitride film are formed in this order, and the oxide film and the nitride film concerned are etched back. Hereby, as shown in FIG. 10, sidewall 8 and spacer 9 are formed.

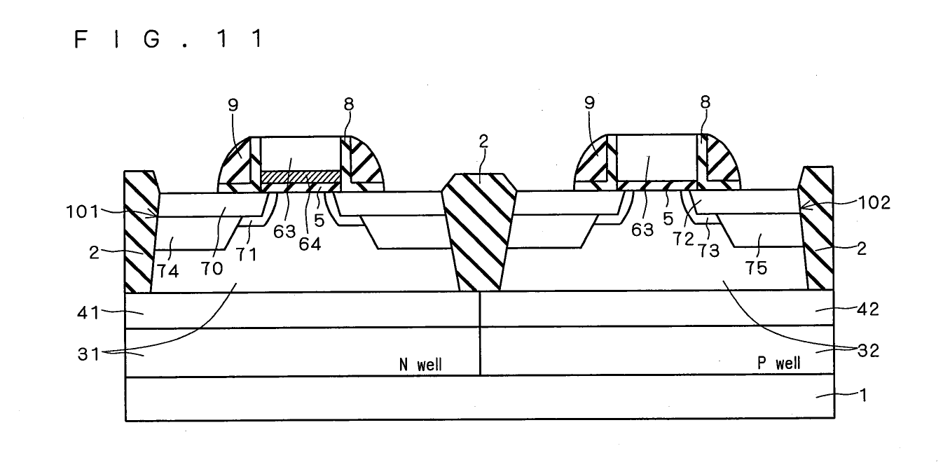

With reference to FIG. 11, in the upper part of N type well 31, main layer 74 is formed by using the laminated structure of polycrystalline silicon layer 63/metal layer 64/gate insulating film 5, and sidewall 8 and spacer 9 of the perimeter as a mask. In the upper part of P type well 32, main layer 75 is formed by using the laminated structure of polycrystalline silicon layer 63/gate insulating film 5, and sidewall 8 and spacer 9 of the perimeter as a mask.

Although not illustrated in detail, when forming main layer 74, the upper part of P type well 32 is covered by photoresist, and P type impurities (for example, boron) are introduced by an ion implantation to N type well 31 also including sublayers 70 and 71. When forming main layer 75 similarly, the upper part of N type well 31 is covered by photoresist, and N type impurities (for example, arsenic) are introduced by an ion implantation to P type well 32 also including sublayers 72 and 73. And annealing for activating source/drain layers 101,102 is performed. For example, lamp annealing is adopted as annealing.

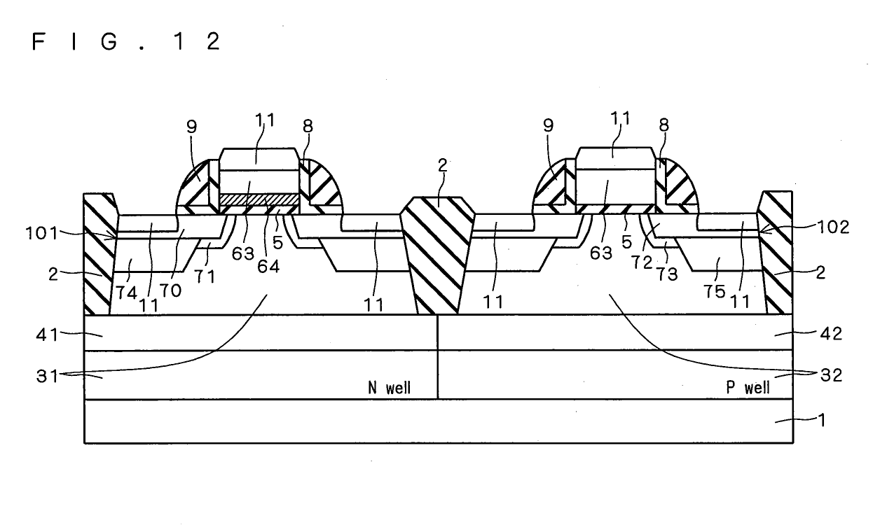

Covering all over the surface exposed at the main surface side, the metal for silicide, for example, cobalt, is formed, and annealing performs the first silicidation. And an unreacted metal for the above-mentioned silicide is removed, the second silicidation is performed performing annealing further, and resistance of silicide is lowered urging the phase transition of silicide. Hereby, as shown in FIG. 12, silicide layer 11 is formed in the exposed surface of source/drain extensions 70 and 72 and polycrystalline silicon layer 63.

Then, interlayer insulation film 12, contact plug 13, and wiring layer 14 are formed by a well-known manufacturing process, and CMOS transistor 501 shown in FIG. 1 is obtained.

As mentioned above, in order to etch metal layer 64 along with etching of polycrystalline silicon layer 63, the thinner one of metal layer 64 is desirable. However, metal layer 64 needs to have a suitable work function, and is considered that thickness of 3 nm or more is required from this request.

### Embodiment 2

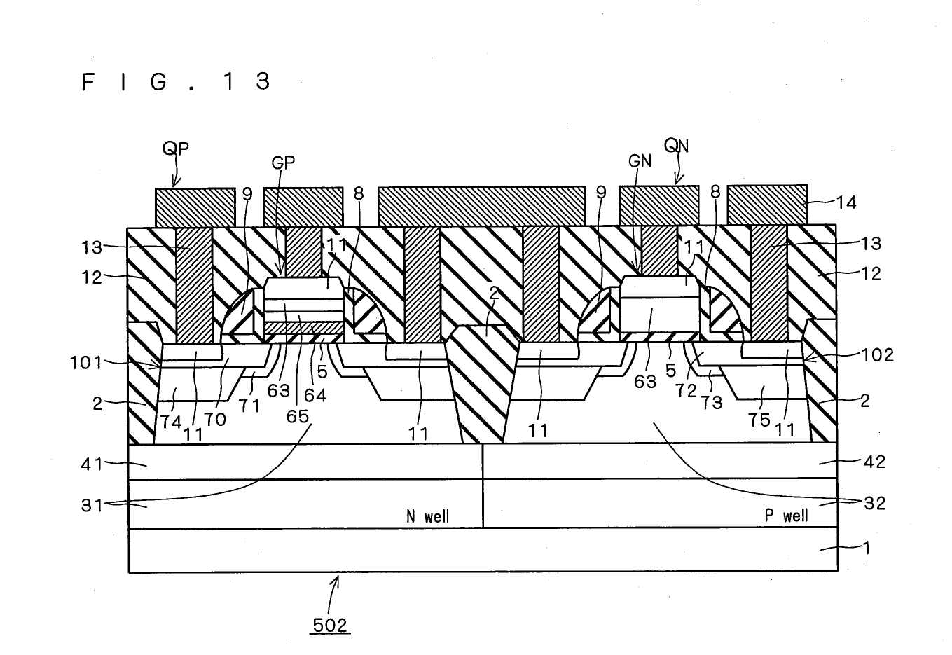

FIG. 13 is a cross-sectional view showing the structure of CMOS transistor 502 concerning this embodiment. CMOS transistor 502 has a characteristic difference in gate electrode GP to CMOS transistor 501.

That is, as for gate electrode GP in this embodiment, silicide layer 65 is added between metal layer 64 and polycrystalline silicon layer 63 to gate electrode GP in Embodiment 1. Silicide layer 65 can be formed with the compound of the same metallic material as metal layer 64, and silicon, for example. For example, when adopting titanium nitride (TiN) as metal layer 64, titanium silicide (TiSi₂) is formed as silicide layer 65. For example, when adopting tungsten nitride (WN) as metal layer 64, tungsten silicide (WSi₂) is formed as silicide layer 65. Of course, when adopting titanium nitride (TiN) as metal layer 64, tungsten silicide (WSi₂) may be formed as silicide layer 65, and when adopting tungsten nitride (WN) as metal layer 64, titanium silicide (TiSi₂) may be formed as silicide layer 65.

The conductivity of gate electrode GN can be increased by forming silicide layer 65 in this way.

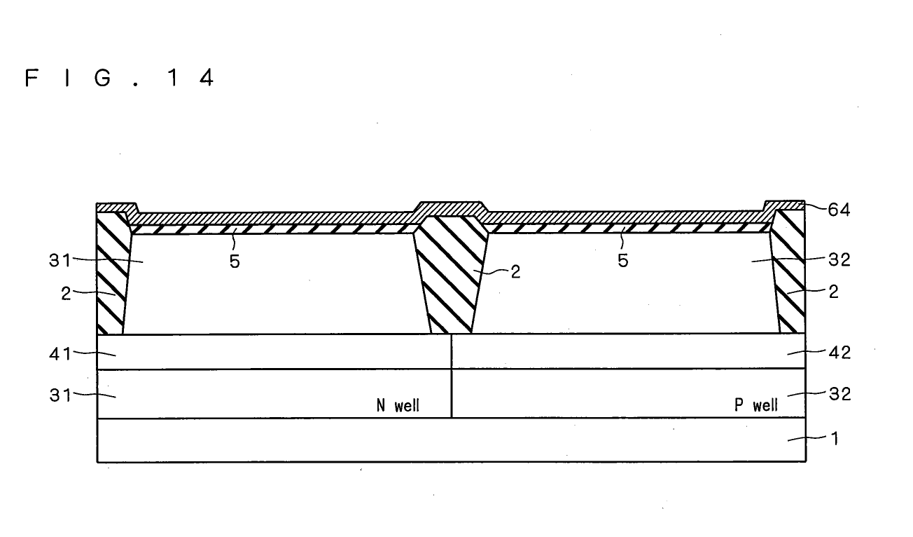

FIG. 14 through FIG. 18 are the cross-sectional views showing the manufacturing process of CMOS transistor 502 in order. For example, the structure shown in FIG. 4 is acquired according to the steps explained by Embodiment 1. Then, over the whole surface exposed at the main surface side, metal layer 64 is formed by the thickness mentioned above on gate insulating film 5, and the structure shown in FIG. 14 is acquired.

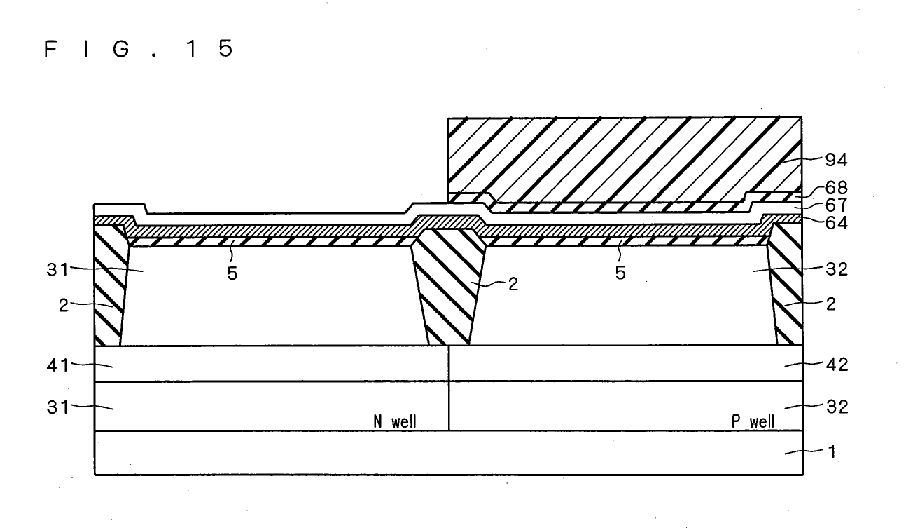

With reference to FIG. 15, polycrystalline silicon layer 67 is formed on metal layer 64, and oxide film 68 is further formed on polycrystalline silicon layer 67. The thickness of polycrystalline silicon layer 67 and oxide film 68 is about 5 nm and 10 nm, respectively, for example. Since polycrystalline silicon layer 67 is used in order to form a silicide layer later, it is not necessary to thicken. Oxide film 68 has a function which prevents the silicidation of polycrystalline silicon layer 67. When forming oxide film 68, it is in low temperature and it is desirable to adopt CVD, for example so that metal layer 64 may not be deteriorated.

Photoresist 94 is formed on oxide film 68 in the upper part of P type well 32, and oxide film 68 is etched by using this as a mask. Then, photoresist 94 is removed. Hereby, oxide film 68 covers polycrystalline silicon layer 67 in the upper part of P type well 32, while exposing polycrystalline silicon layer 67 in the upper part of N type well 31.

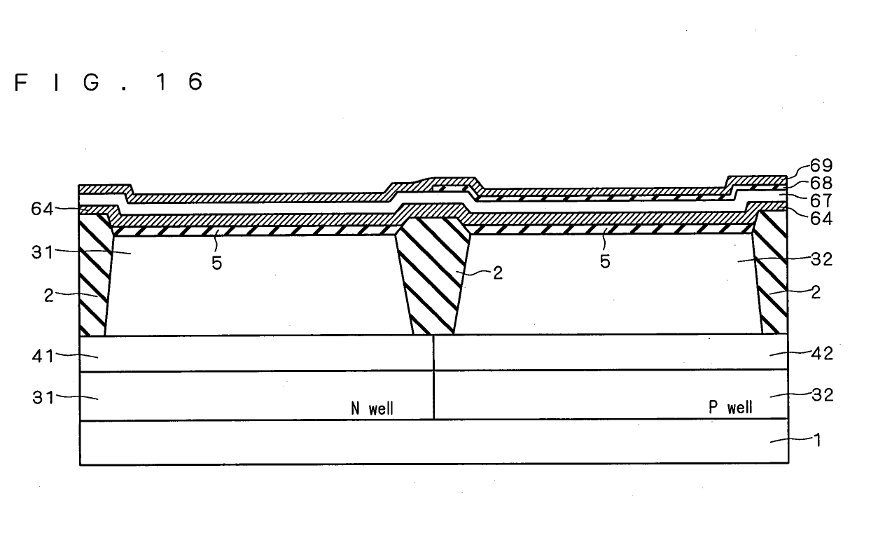

With reference to FIG. 16, metal layer 69 is formed, covering the whole surface exposed at the main surface side. Since metal layer 69 is used for the silicidation of polycrystalline silicon layer 67, titanium (Ti) and tungsten (W) are adopted as a material, for example. Since it is used in order to form a silicide layer, thickness of about 5 nm is sufficient.

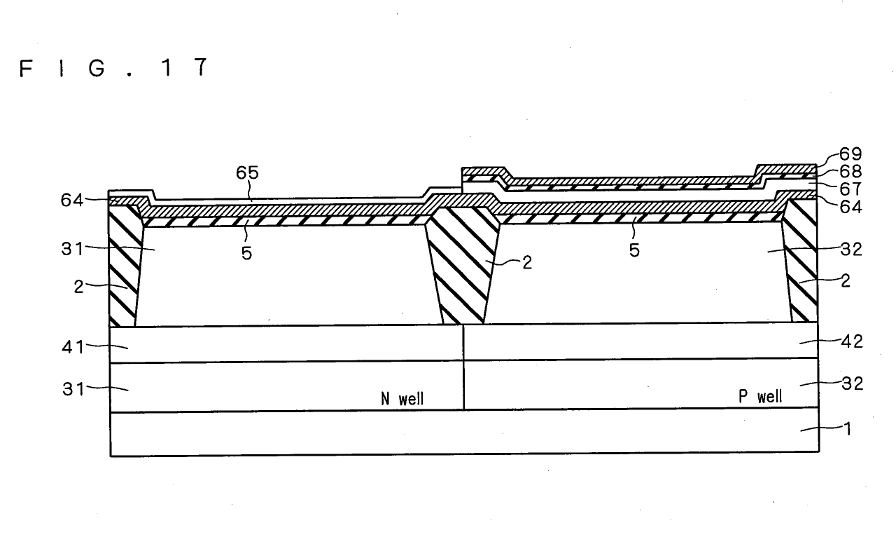

Then, annealing of about 500° C. is performed to the whole. In the upper part of N type well 31, since polycrystalline silicon layer 67 and metal layer 69 touch, a silicidation progresses, but since oxide film 68 intervenes between polycrystalline silicon layer 67 and metal layer 69, a silicidation does not progress in the upper part of P type well 32. Therefore, as shown in FIG. 17, while silicide layer 65 is formed on metal layer 64 in the upper part of N type well 31, in the upper part of P type well 32, polysilicon layer 67, oxide film 68, and metal layer 69 leave on metal layer 64. Then, metal layer 69, oxide film 68, and polysilicon layer 67 are removed.

Thus, oxide film 68 has a function which obstructs a silicidation, and generates a silicidation in self align. Therefore, oxide film 68 does not bear a function as a mask at the time of etching a metal layer like nitride film 61. Therefore, a nitride film may be adopted instead of oxide film 68.

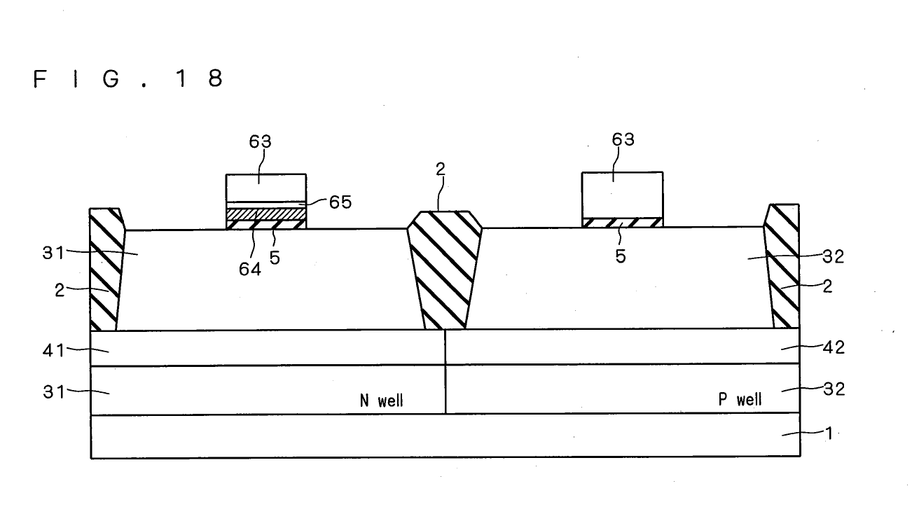

Then, polycrystalline silicon layer 63 is formed, covering the whole surface exposed at the main surface side. In the upper part of N type well 31, polycrystalline silicon layer 63 will be formed on silicide layer 65, and it will be formed on gate insulating film 5 in the upper part of P type well 32. Formation of polycrystalline silicon layer 63 and patterning of polycrystalline silicon layer 63, metal layer 64, silicide layer 65, and gate insulating film 5 can be performed like Embodiment 1, and the structure shown in FIG. 18 is acquired.

Then, the steps explained using FIG. 9 through FIG. 12 by Embodiment 1 are adopted, and CMOS transistor 502 shown in FIG. 13 is obtained.

Besides an above-mentioned structure, polycrystalline silicon layer 67, oxide film 68, and metal layer 69 may be formed before forming metal layer 64, and metal layer 64 may be formed after forming silicide layer 65 after that. In this case, in gate electrode GP, as for CMOS transistor 502, silicide layer 65 intervenes between metal layer 64 and gate insulating film 5.

### Embodiment 3

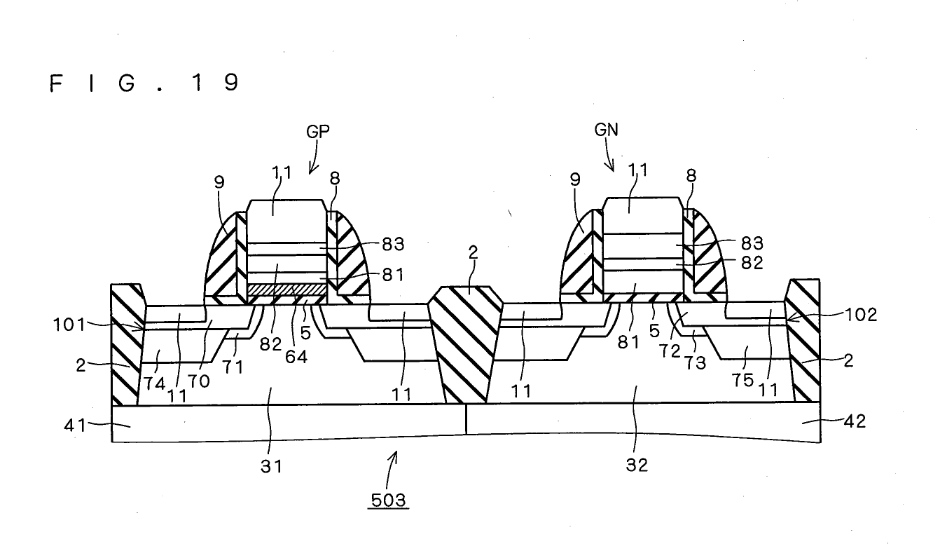

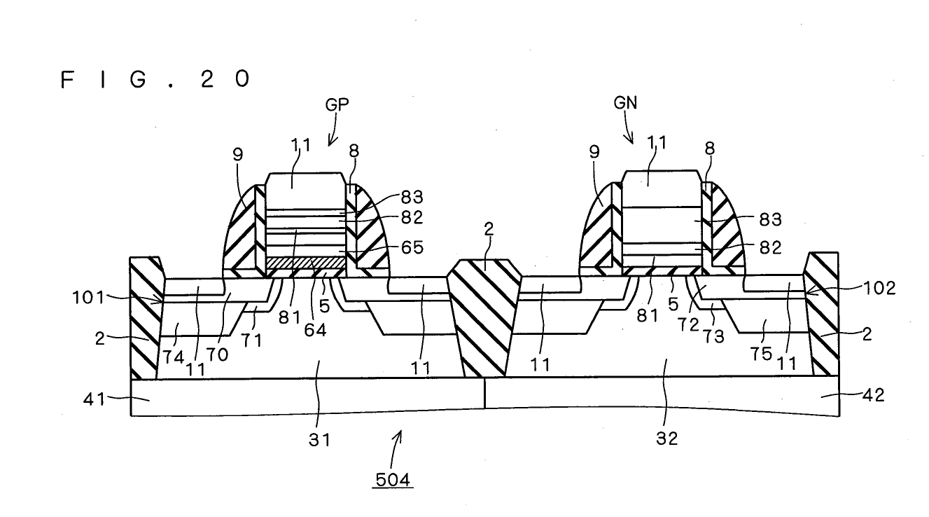

FIG. 19 and FIG. 20 are the cross-sectional views showing the structure of CMOS transistors 503,504 concerning this embodiment. However, the structure of gate electrodes GP and GN is expanded and shown, and in order to avoid the complicatedness of a drawing, semiconductor substrate 1, N type well 31, P type well 32, interlayer insulation film 12, contact plug 13, and wiring layer 14 are omitted.

In CMOS transistor 503, there is a characteristic difference in that polycrystalline silicon layer 63 was replaced by the multilayer structure of polycrystalline silicon layer 81/silicon germanium (SiGe) layer 82/polycrystalline silicon layer 83 to CMOS transistor 501 concerning Embodiment 1. The thickness of polycrystalline silicon layer 81, silicon germanium (SiGe) layer 82, and polycrystalline silicon layer 83 is 10 nm, 20 nm, and 70 nm, respectively. Into polycrystalline silicon layer 81 and 83, phosphorus is introduced by the concentration of 1020 cm-3 as an impurity, for example. The germanium (Ge) concentration in silicon germanium (SiGe) layer 82 is about 15 atom %, for example.

By acquiring above-mentioned multilayer structure, the band structure of gate electrodes GP and GN can be improved, then the electrical property can be improved.

CMOS transistor 504 has the structure which formed silicide layer 65 on metal layer 64 further to the structure of CMOS transistor 503. Silicide layer 65 may be formed between metal layer 64 and gate insulating film 5. The formation of silicide layer 65 can adopt the method shown in Embodiment 2.

The conductivity of gate electrode GN can also be increased improving the band structure of gate electrodes GP and GN by acquiring this multilayer structure.

### Embodiment 4

An amorphous silicon layer may be adopted instead of polycrystalline silicon layer 63 shown by Embodiment 1 through Embodiment 3. Amorphous silicone is easy in micro fabrication as compared with polycrystalline silicon, and contributes to integration of a CMOS transistor.

### Embodiment 5

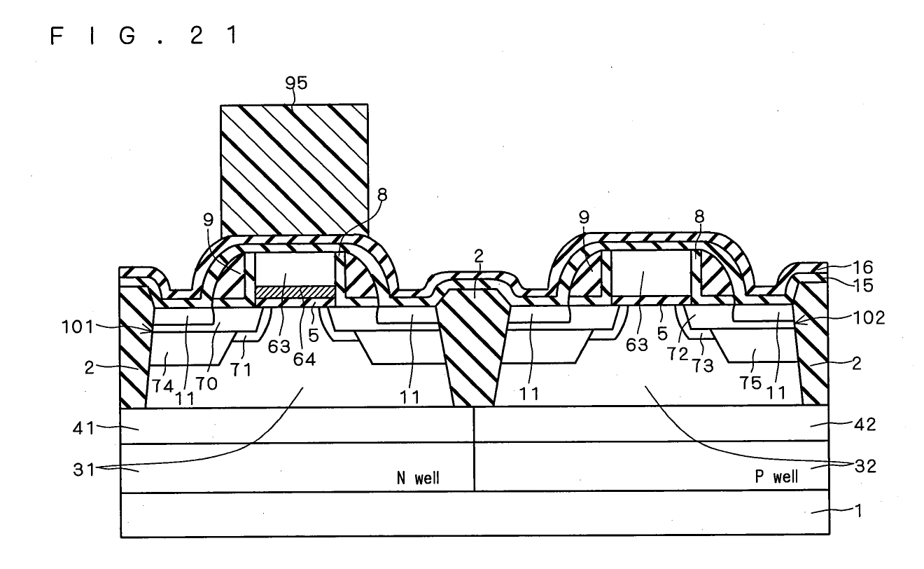

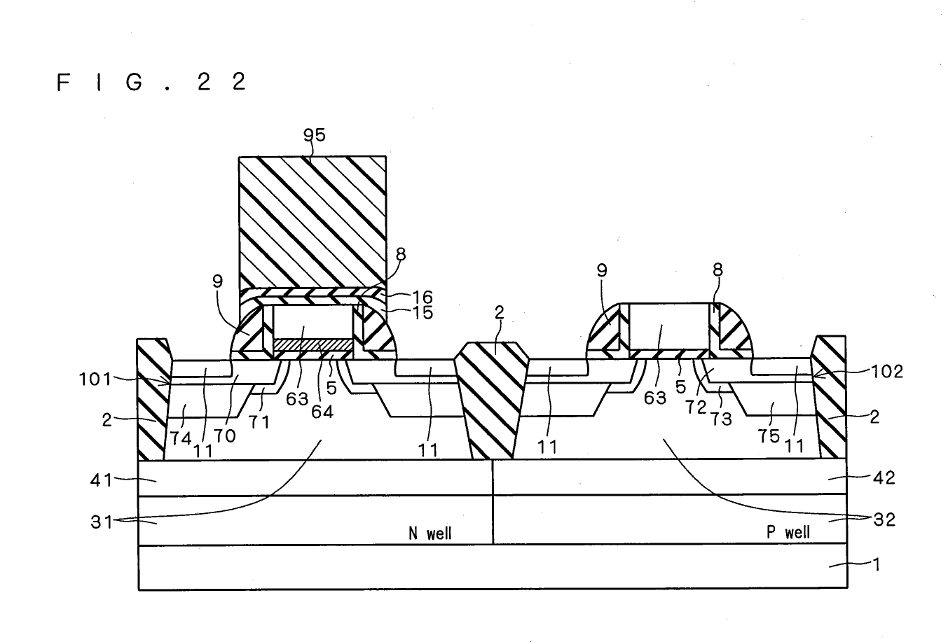

FIG. 21 and FIG. 22 are the cross-sectional views showing the manufacturing method of the CMOS transistor concerning this embodiment at process order. The manufacturing method shown by this embodiment is employable in the manufacturing process of the CMOS transistor shown in Embodiment 1 through Embodiment 4. Below, in order to avoid the complicatedness of drawings, it explains taking an example of the case where CMOS transistor 501 shown in Embodiment 1 is manufactured.

After acquiring the structure shown in FIG. 11, before performing annealing for activating source/drain layers 101,102, oxide film 15 and nitride film 16 are formed in this order, covering all over the surface exposed at the main surface side. And photoresist 95 is formed covering metal layer 64, and the structure shown in FIG. 21 is acquired. For example, the thickness of oxide film 15 and nitride film 16 is 10 nm and 20 nm, respectively, and all can be formed with CVD.

With reference to FIG. 22, oxide film 15 and nitride film 16 are patterned by etching which uses photoresist 95 as a mask. Then, photoresist 95 is removed and lamp annealing for activating source/drain layers 101,102 is performed. The conditions of, for example more than or equal to 1000° C. and for 3 or less seconds are adopted as lamp annealing, and it is carried out from the upper part of nitride film 6.

Then, nitride film 16 is removed, for example using hot phosphoric acid, and oxide film 15 is also removed further. Then, the process progresses to the step which forms silicide layer 11 (FIG. 12).

Nitride film 16 functions as a light shielding film to the lamp adopted by lamp annealing. Therefore, in the case of lamp annealing, it can be avoided that the temperature of metal layer 64 rises, and the melting of metal layer 64 can be avoided. On the other hand, as for nitride film 16, since it is necessary to activate source/drain layers 101,102, it is desirable to form with the dimension which does not cover source/drain layers 101,102 although the upper part of metal layer 64 is covered. For example, the end portion of photoresist 95 exists on spacer 9. Hereby, nitride film 16 is also patterned to the same configuration.

(Modification)

Contrary to the above-mentioned explanation, the case adopting a metal layer in the gate electrode in an NMOS transistor and not adopting a metal layer in a PMOS transistor is also included in the present invention. When aluminium oxide (Al₂O₃) and aluminium silicon nitride (AlSiN) are adopted especially as a gate insulating film, it is desirable to adopt a metal layer as the gate electrode in an NMOS transistor. When adopting silicon as a main component of P type well 32, it is desirable to have a work function (about 4.0 eV) near the conduction band of silicon as a material of the metal layer concerned. As a material which has this work function, titanium (Ti), zirconium (Zr), vanadium (V), tantalum (Ta), aluminium (Al), niobium (Nb), tantalum nitride (TaN), and tantalum silicon nitride (TaSiN) can be mentioned.

When aluminium nitride is especially adopted as gate insulating film 5 and polycrystalline silicon layer 63 of gate electrode GN contacts gate insulating film 5, it is easy to generate the problem of an interface state called the so-called fermi pinning. However, by adopting the above-mentioned metal layer between gate insulating film 5 and polycrystalline silicon layer 63, this problem is also avoidable. Therefore, the present invention is preferred, when adopting aluminium nitride as gate insulating film 5 and raising the dielectric constant.

The present invention is not limited to a CMOS transistor and can be applied to a plurality of MOS transistors which adopt a different threshold value. When it is a transistor which has a MOS structure, without being limited to a field effect transistor, it is clear that it is applicable also to an insulated gate type bipolar transistor (IGBT).

What is claimed is:

1. A semiconductor device including a PMOS and an NMOS each having a gate, a source and a drain, comprising:
a semiconductor substrate having the PMOS forming region and the NMOS forming region;
a first source and a first drain regions having a first conductivity type formed in the semiconductor substrate and into the PMOS forming region;
a second source and a second drain regions having a second conductivity type which is opposite to the first conductivity type, formed in the semiconductor substrate and into the NMOS forming region;
a first channel forming region formed between the first source region and the first drain region;
a second channel forming region formed between the second source region and the second drain region;
a first gate insulating film formed on the first channel region;
a second gate insulating film formed on the second channel region;
a metal layer formed on the first gate insulating film;
a silicide layer formed on the metal layer;
a first silicon layer formed on the silicide layer; and
a second silicon layer formed on the second gate insulating film,
wherein the metal layer, the silicide layer and the first silicon layer constitute a gate electrode of the PMOS, and the second silicon layer constitutes a gate electrode of the NMOS.

2. A semiconductor device according to claim 1, wherein
the silicide layer is formed with a compound of the same metallic material as the metal layer.
